(19) United States
(12) Patent Application Publication
(10) Pub. No.: US 2025/0324914 A1
(43) Pub. Date: Oct. 16, 2025

(54) SEMICONDUCTOR DEVICE, SEMICONDUCTOR SYSTEM, AND METHOD OF MANUFACTURING SEMICONDUCTOR DEVICE

(71) Applicants: Samsung Electronics Co., Ltd., Suwon-si (KR); SEOUL NATIONAL UNIVERSITY R&DB FOUNDATION, Seoul (KR)

(72) Inventors: Hyungjun YOUN, Suwon-si (KR); Gyu-Chul YI, Seoul (KR); Jaewon KIM, Suwon-si (KR); Won Joon CHO, Suwon-si (KR); Seong Beom KIM, Seoul (KR); Eun Su LEE, Seoul (KR); Taehoon KIM, Suwon-si (KR); Woochang LEE, Suwon-si (KR); Jae Hong LEE, Suwon-si (KR); Hyeongseok JANG, Suwon-si (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 19/176,827

(22) Filed: Apr. 11, 2025

(30) Foreign Application Priority Data
Apr. 12, 2024 (KR) 10-2024-0049461

(51) Int. Cl. H10N 50/10; G11C 11/16; H10N 50/01; H10N 50/85

(52) U.S. Cl. CPC H10N 50/10; G11C 11/161; H10N 50/01; H10N 50/85

(57) ABSTRACT

A semiconductor device, a semiconductor system, and a method of manufacturing a semiconductor device are provided. The semiconductor device includes a reference layer with a fixed spin direction, a barrier layer below the reference layer, a free layer below the barrier layer and having a spin direction switchable by current, and a spin orbit coupling (SOC) layer below the free layer and containing different types of topological materials.

### CROSS-REFERENCE TO RELATED APPLICATION

This application claims priority to and the benefit of Korean Patent Application No. 10-2024-0049461 filed at the Korean Intellectual Property Office on Apr. 12, 2024, the entire contents of which are incorporated herein by reference.

### BACKGROUND

### 1. Field

The present disclosure relates to semiconductor devices, semiconductor systems, and methods of manufacturing a semiconductor device.

### 2. Description of the Related Art

Spintronics technology is attracting attention as a technology to overcome the technical limitations of classical semiconductor devices that control electrons using electric fields and use electronic charges. Spintronics technology is a technology that controls electrons and the spin of electrons using magnetic fields. Spintronic semiconductor devices store information using the spin of electrons, enabling higher processing speeds and lower power consumption.

In this regard, spin orbit torque (SOT) is a phenomenon that controls the direction of magnetization within a magnetic material using the spin orbit coupling (SOC) effect. When current flows through a material in an SOT-based device, such as spin orbit torque magnetic random access memory (SOT-MRAM), the spin of electrons may be polarized in a specific direction due to spin-orbit coupling. When the spin-polarized current passes through the magnetic layer, the region in the magnetization direction is rearranged according to the exchange interaction between the spin of the electron and the magnetic moment of the magnetic layer, so SOT may provide an effective method for converting the magnetization direction within a magnetic material.

### SUMMARY

The present disclosure attempts to provide to semiconductor devices capable of engineering the physical quantities of spin orbit torque (SOT) to secure physical properties capable of achieving high SOT efficiency, low switching power density, and low resistivity, and increase device efficiency.

A semiconductor device according to an example embodiment may include a reference layer with a fixed spin direction, a barrier layer below the reference layer, a free layer below the barrier layer and having a spin direction switchable by current, and a spin orbit coupling (SOC) layer below the free layer and containing different types of topological materials.

In some example embodiments, the different types of topological materials may include a first topological material and a second topological material, and the SOC layer may include a substrate, and a thin film layer on the substrate, the thin film layer including the first topological material and the second topological material that are alternately stacked on each other

In some example embodiments, the first topological material may include a topological insulator, and the second topological material may include a topological semimetal.

In some example embodiments, the topological insulator may include at least one of Bi₂Te₃, Sb₂Te₃, or Bi₂Se₃.

In some example embodiments, the topological semimetal may include at least one of WTe₂, ZrTe₅, EuMnBi₂, or CaIrO₂.

In some example embodiments, the topological insulator may include a first topological insulator layer and a second topological insulator layer, the topological semimetal may include a first topological semimetal layer, the first topological insulator layer may be on the substrate, the first topological semimetal layer may be on the first topological insulator layer, the second topological insulator layer may be on the first topological semimetal layer, and the free layer may be on the second topological insulator layer.

In some example embodiments, the topological insulator may include a first topological insulator layer, the topological semimetal may include a first topological semimetal layer, the first topological insulator layer may be on the substrate, the first topological semimetal layer may be on the topological insulator layer, and the free layer may be on the first topological semimetal layer.

In some example embodiments, the topological insulator may include a first topological insulator layer, the topological semimetal may include a first topological semimetal layer and a second topological semimetal layer, the first topological semimetal layer may be on the substrate, the first topological insulator layer may be on the first topological semimetal layer, the second topological semimetal layer may be on the first topological insulator layer, and the free layer may be on the second topological semimetal layer.

In some example embodiments, the topological insulator may include a first topological insulator layer, the topological semimetal may include a first topological semimetal layer, the first topological semimetal layer may be on the substrate, the first topological insulator layer may be on the first topological semimetal layer, and the free layer may be on the first topological insulator layer.

In some example embodiments, the substrate may include at least one of silicon or sapphire.

A semiconductor system according to an example embodiment may include a processor, a memory, and a storage, wherein at least one of a cache of the processor, the memory, or the storage includes a semiconductor device implemented with a spin orbit torque magnetic random access memory (SOT-MRAM), and the semiconductor device includes a spin orbit coupling (SOC) layer containing different types of topological materials.

In some example embodiments, the SOC layer may include a substrate, and a thin film layer on the substrate, the thin film layer including the different types of topological materials, the different types of topological material layers including at least one first topological material and at least one second topological material that are alternately stacked on each other.

In some example embodiments, the at least one first topological material may include a topological insulator, and the at least one second topological material may include a topological semimetal.

In some example embodiments, the topological insulator may include at least one of Bi₂Te₃, Sb₂Te₃, or Bi₂Se₃.

In some example embodiments, the topological semimetal may include at least one of WTe₂, ZrTe₅, EuMnBi₂, or CaIrO₂.

A method of manufacturing a semiconductor device according to an example embodiment may include forming a spin orbit coupling (SOC) layer containing different types of topological materials, forming a free layer on the SOC layer with a spin direction switchable by current, forming a barrier layer on the free layer, and forming a reference layer with a fixed spin direction on the barrier layer.

In some example embodiments, the forming of the SOC layer may include providing a substrate, and providing the different types of topological material layers on the substrate by forming a first topological insulator layer on the substrate, forming a first topological semimetal layer on the first topological insulator layer, and forming a second topological insulator layer on the first topological semimetal layer.

In some example embodiments, the forming of the SOC layer may include providing a substrate, and providing the different types of topological material layers on the substrate by forming a first topological insulator layer on the substrate, forming a first topological semimetal layer on the first topological insulator layer.

In some example embodiments, the forming of the SOC layer may include providing the substrate, and providing the different types of topological material layers on the substrate by forming a first topological semimetal layer on the substrate, forming a first topological insulator layer on the first topological semimetal layer, and forming a second topological semimetal layer on the first topological insulator layer.

In some example embodiments, the forming of the SOC layer may include providing a substrate, and providing the different types of topological material layers on the substrate by forming a first topological semimetal layer on the substrate, forming a first topological insulator layer on the first topological semimetal layer.

### BRIEF DESCRIPTION OF THE DRAWINGS

FIG. 1 illustrates a semiconductor device according to an example embodiment.

FIG. 2 illustrates an SOC layer of a semiconductor device according to an example embodiment.

FIGS. 3 and 4A-4C illustrate implementations of other semiconductor devices according to some example embodiments.

FIG. 5 illustrates an SOC layer of a semiconductor device according to an example embodiment.

FIG. 6 illustrates an SOC layer of a semiconductor device according to an example embodiment.

FIG. 7 illustrates an SOC layer of a semiconductor device according to an example embodiment.

FIGS. 8 to 11 illustrate a method of manufacturing a semiconductor device according to an example embodiment.

FIG. 12 is a block diagram illustrating a semiconductor system including a semiconductor device according to an example embodiment.

### DETAILED DESCRIPTION

The present disclosure will be described in detail hereinafter with reference to the accompanying drawings, in which some example embodiments of the present disclosure are shown. As those skilled in the art would realize, the described example embodiments may be modified in various different ways, all without departing from the spirit or scope of the present inventive concepts. Accordingly, the drawings and description are to be regarded as illustrative in nature and not restrictive. Like reference numerals designate like elements throughout the specification.

Throughout the specification and claims, unless explicitly described to the contrary, the word “comprise,” and variations such as “comprises” or “comprising,” will be understood to imply the inclusion of stated elements but not the exclusion of any other elements. Although terms “first,” “second,” and the like are used to explain various constituent elements, the constituent elements are not limited to such terms. These terms are only used to distinguish one constituent element from another constituent element.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

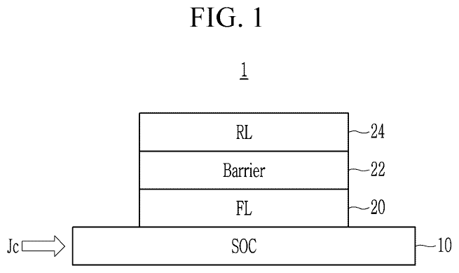

FIG. 1 illustrates a semiconductor device according to an example embodiment.

Referring to FIG. 1, a semiconductor device 1 according to an example embodiment may include a spin orbit coupling (SOC) layer 10, a free layer 20, a barrier layer 22, and a reference layer 24. As shown, the semiconductor device 1 may be formed in a stacked structure in which the SOC layer 10, the free layer 20, the barrier layer 22, and the reference layer 24 are stacked. In the stacked structure, the barrier layer 22 may be formed below the reference layer 24, the free layer 20 may be formed below the barrier layer 22, and the SOC layer 10 may be formed below the free layer 20.

The SOC layer 10 may record a specific spin direction in the free layer 20 using current. For example, electrodes (not shown) may be formed on the lower surface of the left end of the SOC layer 10 and the lower surface of the right end of the SOC layer 10, respectively, and current J_{c} may flow from one of the electrodes (for example, the electrode formed on the lower surface of the left end of the SOC layer 10) to the other (for example, the electrode formed on the lower surface of the right end of the SOC layer 10). In some example embodiments, the electrodes may include at least one of Ta, TiN, TaN, Ru, Au, W, or Cu. The current J_{c} provides a spin orbit torque (SOT) to switch the magnetic moment of the free layer 20, thereby causing a change in resistance of the semiconductor device 1. For example, depending on whether the spin direction recorded in the free layer 20 by the SOT is the same as the spin direction recorded in the reference layer 24, the resistance value between the free layer 20 and the reference layer 24 may vary, and the resistance value may be used to determine the data value of a cell in an SOT-based device such as a spin orbit torque magnetic random access memory (SOT-MRAM). The magnetic moment may be orthogonal to the plane of current J_{c} flow. The detailed configuration of the SOC layer 20 will be described later.

The free layer 20 may have a spin direction that is switchable by current. That is, the magnetic moment of the free layer 20 may be switched by the torque induced by the spin-orbit interaction effect. In some example embodiments, the free layer 20 may include at least one of Fe, Co, or Ni, or may include at least one of B, Si, Zr, Pt, Pd, Cu, or W.

The reference layer 24 may have a fixed spin direction. As described above, since the free layer 20 has a spin direction switched by the current, the magnetization within the free layer 20 may be parallel or anti-parallel to the magnetization of the reference layer 24. Data may be written into the cells of an SOT-based device by applying current perpendicular to the stacked structure. In some example embodiments, the reference layer 24 may include at least one of Fe, Co, or Ni, or may include at least one of B, Si, Zr, Pt, Pd, Cu, or W.

The barrier layer 22 may be made of an insulating material with a thickness thin sufficient to allow electrons to travel through tunneling—for example, a few nanometers (nm) thick. The barrier layer 22 may be made of a material such as MgO, Al₂O₃, or the like. In general, MgO is widely used because it has a relatively high tunnel magnetoresistance ratio (TMR), which is good in terms of performance and stability, but Al₂O₃ may still be used in some applications.

It is important to note that the stacked structure of the free layer 20, barrier layer 22, and reference layer 24 formed on the SOC layer 10 is not limited to the form shown in FIG. 1. It is clear that, with the SOC layer 10 described herein, the stacked structure formed on the SOC layer 10 may be formed as a structure including various combinations of one or more free layers and one or more reference layers, without being limited to that shown in FIG. 1. In other words, the SOC layer 10 may provide a platform for magnetic materials without imposing restrictions on the stacked structure formed thereon.

The SOC layer 10 may include different types of topological materials. A topological material is a material whose electronic structure has specific topological characteristics, with a topological insulator being an example of the topological material.

The topological insulator is an insulator whose interior cannot allow electrons to pass through, but has channels through which current may flow along the surface or edge due to the topologically protected spin momentum locking effect. Due to the effect, the topological insulator is a group of materials that have surface conductivity that is not affected by internal defects or impurities, and have a greater spin orbit torque efficiency per unit current compared to other materials.

The topological insulator also has lower switching current density, especially compared to heavy metal ferromagnetic heterostructures. However, the topological insulator has a high specific resistance due to limitation of internal current flow and thus has a relatively high power density, which may be a limiting factor in industrial application purposes. To overcome this limitation, the SOC layer 10 may include a topological insulator and other materials in a heterostructure. Here, the other material may be, for example, a topological semimetal.

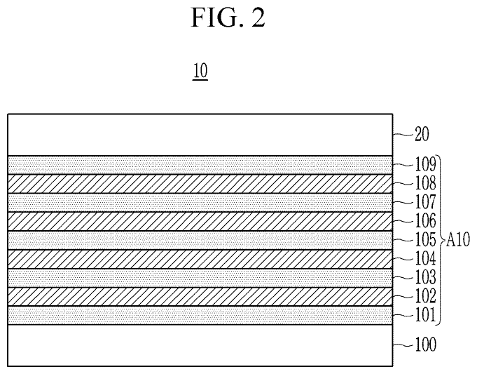

FIG. 2 illustrates an SOC layer of a semiconductor device according to an example embodiment.

Referring to FIG. 2, the SOC layer 10 of a semiconductor device according to an example embodiment may include a first topological material and a second topological material as different types of topological materials, and the SOC layer 10 may include a substrate 100 and a thin film layer A10. The thin film layer A10 may be formed by alternately stacking the first topological material and the second topological material on the substrate 100. In some example embodiments, the substrate 100 may include at least one of silicon or sapphire.

In the present example embodiment, the first topological material may include a topological insulator, and the second topological material may include a topological semimetal. In some example embodiments, the topological insulator may include at least one of Bi₂Te₃, Sb₂Te₃, or Bi₂Se₃, and the topological semimetal may include at least one of WTe₂, ZrTe₅, EuMnBi₂, or CaIrO₂.

The thin film layer A10 may include one or more topological insulator layers 101, 103, 105, 107, and 109 as topological insulators and one or more topological semimetal layers 102, 104, 106, and 108 as topological semimetals. In the thin film layer A10, the topological insulator layer 101 may be formed on the substrate 100, the topological semimetal layer 102 may be formed on the topological insulator layer 101, the topological insulator layer 103 may be formed on the topological semimetal layer 102, and the topological semimetal layer 104 may be formed on the topological insulator layer 103. Stacking may be repeated in this pattern and the free layer 20 may be formed on the topological insulator layer 109.

A stacked structure of the free layer 20, the barrier layer 22, and the reference layer 24 may be formed on the SOC layer 10 in the form shown in FIG. 1. In some example embodiments, the stacked structure formed on the SOC layer 10 is not limited to that shown in FIG. 1, and may be formed as a structure including various combinations of one or more free layers and one or more reference layers.

According to the present example embodiment, it is possible to effectively engineer the physical quantities of the SOT by providing SOT layers containing different types of topological materials. Specifically, by adopting a heterostructure of topological insulators and topological semimetals with different types of topological materials, it is possible to take advantage of the low switching power density of topological insulators while solving the problem of high resistivity due to internal current flow restriction, which is a weakness of topological insulators. Because the heterostructure increases the surface-to-volume ratio of the topological insulator, which increases the amount of surface channels with relatively low resistivity that allow current to flow well per unit volume, overall resistivity is ultimately increased. From this, the power density consumption may be lowered.

In addition, two-dimensional electronic structures may be formed between the interfaces of different types of topological materials in heterostructures, which may also lead to changes in electronic transport characteristics such as charge carrier density and mobility.

Meanwhile, by adopting a heterostructure, it is possible to increase growth stability and reduce the defect rate by inserting a material that is relatively difficult to grow (e.g., a topological semimetal material such as WTe₂) between materials that are relatively easy to grow with high quality. Further, by repeatedly stacking and growing heterostructure forms, the amount of material per unit volume may be increased, thus enhancing or maximizing the properties of the SOT by increasing the thickness of the thin film to allow the flow of sufficient current to drive the SOT device.

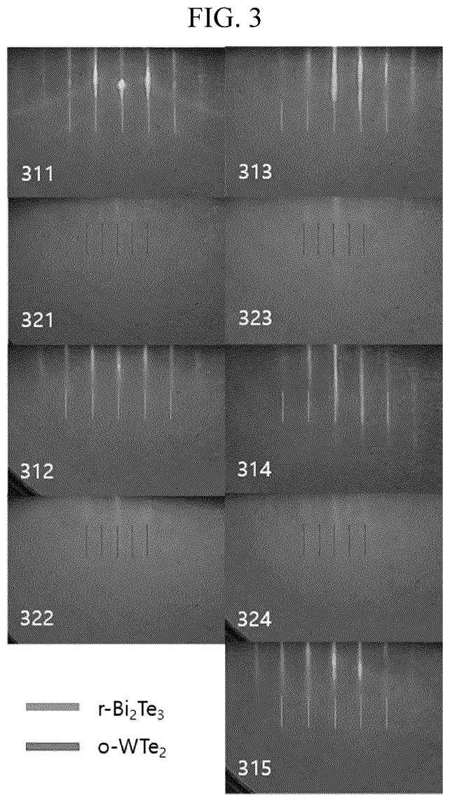

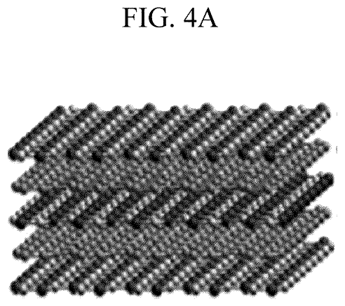

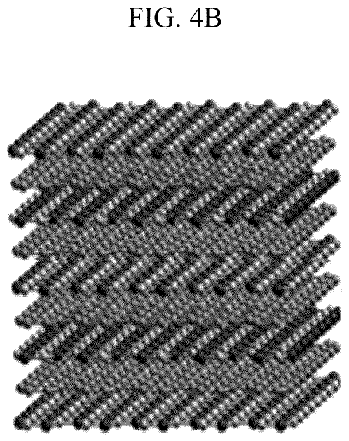

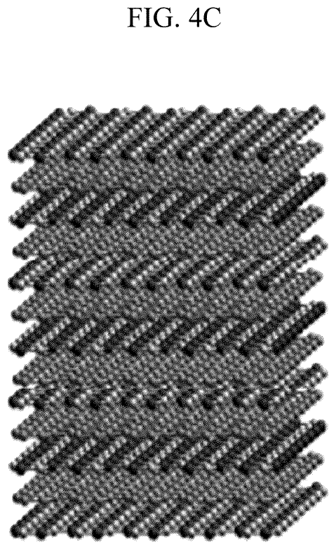

FIGS. 3 and 4A-4C illustrate implementations of other semiconductor devices according to some example embodiments.

Referring to FIG. 3, Bi₂Te₃ (31n), one of the topological insulators, was grown on a two-dimensional material on a substrate using molecular beam epitaxy (MBE), and then WTe₂ (32n), one of the topological semimetals, was directly grown to create a heterojunction structure, and the process was repeated to implement the heterostructure, and then the diffraction pattern of each material was confirmed as a Reflection High-Energy Electron Diffraction (RHEED) pattern by in-situ RHEED. Here, in-situ RHEED is a diffraction-based diagnostic technology capable of monitoring the surface and structural changes of a thin film in real time during the process of thin film growth.

The thin film layer shown in FIG. 3 may include one or more topological insulator layers 311, 312, 313, 314, and 315 as topological insulators and one or more topological semimetal layers 321, 322, 323, and 324 as topological semimetals. As can be seen from the RHEED pattern, in the thin film layer, the topological semimetal layer 321 may be formed on the topological insulator layer 311, the topological insulator layer 312 may be formed on the topological semimetal layer 321, and the topological semimetal layer 322 may be formed on the topological insulator layer 312. Stacking of the layers 313, 323, 314, 324, and 315 may be repeated in this pattern, and a free layer may be formed on the topological insulator layer 315.

Molecular beam epitaxy is a technology that grows high-purity and high-precision thin films by precisely depositing atomic or molecular layers one by one on a single crystal substrate in an ultra-high vacuum. In molecular beam epitaxy, a two-dimensional material with a high-quality single crystal structure is directly grown or transferred onto a substrate, and heat is applied to the substrate on which the two-dimensional material layer is formed in a chamber under an ultra-high vacuum to clean the surface. The temperature at which the two-dimensional material layer is cleaned through heat treatment is determined depending on the material being grown, and the treatment is performed at a somewhat higher temperature than the growth temperature (e.g., a temperature range of about 400° C. to about 820° C.). The amount of input of the elements included in the material to be grown may be controlled using a thermal effusion cell, an e-beam evaporator, or the like. Representative examples of materials to be grown include Bi, Sb, Te, Se, W, or the like, and are not limited to the materials listed, but may be any material desired for a magnetic device. The first thin film layer is formed by adjusting appropriate growth parameters (e.g., growth temperature, growth time, size of inflow, ratio of inflow, or the like), and during the thin film synthesis step, the growth thickness and crystallinity are inferred by observation with in-situ RHEED, and thin films may be synthesized. A heterostructure may be created by growing the second thin film layer in the same way as the first thin film layer. If desired, the process of growing a thin film layer may be repeated to create a heterostructure in a repetitive form. After formation of a thin film layer of a thickness and a structure desired for the device, a magnetic layer can be grown to the top according to the characteristics of the material and bonded to the thin film layer.

In an example embodiment, the thin film layer of the SOC layer may be formed of a heterostructure including five layers in total, including two topological semimetal layers between three topological insulator layers, as shown in FIG. 4A. In another example embodiment, the thin film layer of the SOC layer may be formed as a heterostructure including nine layers in total, including four topological semimetal layers between five topological insulator layers, as shown in FIG. 4B. In still another example embodiment, the thin film layer of the SOC layer may be formed as a heterostructure including thirteen layers in total, including six topological semimetal layers between seven topological insulator layers, as shown in FIG. 4C.

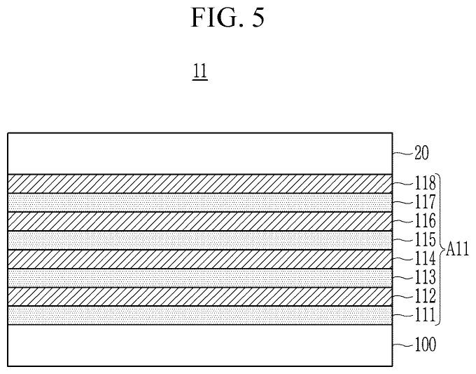

FIG. 5 illustrates an SOC layer of a semiconductor device according to an example embodiment.

Referring to FIG. 5, an SOC layer 11 of the semiconductor device according to an example embodiment may be formed by alternately stacking the first topological material and the second topological material on the substrate 100. The substrate 100 may include at least one of silicon or sapphire.

A thin film layer A11 may include one or more topological insulator layers 111, 113, 115, and 117 as topological insulators and one or more topological semimetal layers 112, 114, 116, and 118 as topological semimetals. In the thin film layer A11, the topological insulator layer 111 may be formed on the substrate 100, the topological semimetal layer 112 may be formed on the topological insulator layer 111, the topological insulator layer 113 may be formed on the topological semimetal layer 112, and the topological semimetal layer 114 may be formed on the topological insulator layer 113. Stacking may be repeated in this pattern, and the free layer 20 may be formed on the topological semimetal layer 118. The topological insulator may include at least one of Bi₂Te₃, Sb₂Te₃, or Bi₂Se₃, and the topological semimetal may include at least one of WTe₂, ZrTe₅, EuMnBi₂, or CaIrO₂.

A stacked structure of the free layer 20, the barrier layer 22, and the reference layer 24 may be formed on the SOC layer 11 in the form shown in FIG. 1. In some example embodiments, the stacked structure formed on the SOC layer 11 is not limited to that shown in FIG. 1, and may be formed as a structure including various combinations of one or more free layers and one or more reference layers.

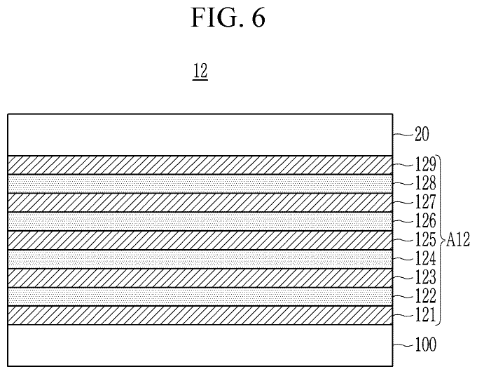

FIG. 6 illustrates an SOC layer of a semiconductor device according to an example embodiment.

Referring to FIG. 6, an SOC layer 12 of a semiconductor device according to an example embodiment may be formed by alternately stacking the first topological material and the second topological material on the substrate 100. The substrate 100 may include at least one of silicon or sapphire.

A thin film layer A12 may include one or more topological semimetal layers 121, 123, 125 and 127 as topological semimetals and one or more topological insulator layers 122, 124, 126 and 128 as topological insulators. In the thin film layer A12, the topological semimetal layer 121 may be formed on the substrate 100, the topological insulator layer 122 may be formed on the topological semimetal layer 121, the topological semimetal layer 123 may be formed on the topological insulator layer 122, and the topological insulator layer 124 may be formed on the topological semimetal layer 123. Stacking may be repeated in this pattern. and the free layer 20 may be formed on the topological semimetal layer 129. The topological insulator may include at least one of Bi₂Te₃, Sb₂Te₃, or Bi₂Se₃, and the topological semimetal may include at least one of WTe₂, ZrTe₅, EuMnBi₂, or CaIrO₂.

A stacked structure of the free layer 20, the barrier layer 22, and the reference layer 24 may be formed on the SOC layer 12 in the form shown in FIG. 1. In some example embodiments, the stacked structure formed on the SOC layer 12 is not limited to that shown in FIG. 1, and may be formed as a structure including various combinations of one or more free layers and one or more reference layers.

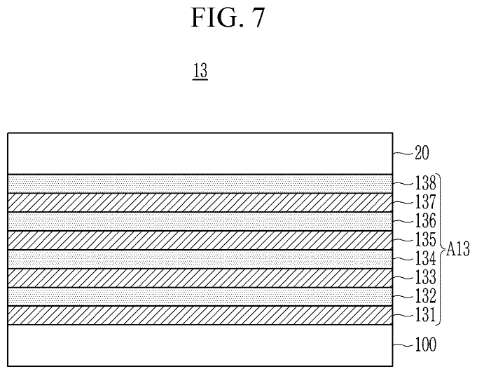

FIG. 7 illustrates an SOC layer of a semiconductor device according to an example embodiment.

Referring to FIG. 7, an SOC layer 13 of a semiconductor device according to an example embodiment may be formed by alternately stacking the first topological material and the second topological material on the substrate 100. The substrate 100 may include at least one of silicon or sapphire.

A thin film layer A13 may include one or more topological semimetal layers 131, 133, 135, and 137 as topological semimetals and one or more topological insulator layers 132, 134, 136, and 138 as topological insulators. In the thin film layer A13, the topological semimetal layer 131 may be formed on the substrate 100, the topological insulator layer 132 may be formed on the topological semimetal layer 131, the topological semimetal layer 133 may be formed on the topological insulator layer 132, and the topological insulator layer 134 may be formed on the topological semimetal layer 133. Stacking may be repeated in this pattern and the free layer 20 may be formed on the topological insulator layer 138. The topological insulator may include at least one of Bi₂Te₃, Sb₂Te₃, or Bi₂Se₃, and the topological semimetal may include at least one of WTe₂, ZrTe₅, EuMnBi₂, or CaIrO₂.

A stacked structure of the free layer 20, the barrier layer 22, and the reference layer 24 may be formed on the SOC layer 13 in the form shown in FIG. 1. In some example embodiments, the stacked structure formed on the SOC layer 13 is not limited to that shown in FIG. 1, and may be formed as a structure including various combinations of one or more free layers and one or more reference layers.

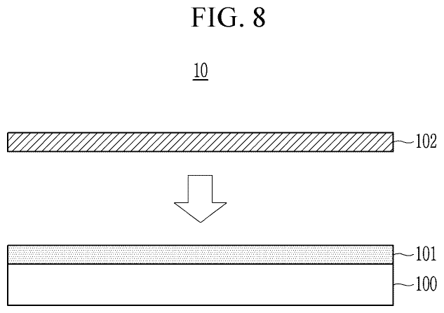

FIGS. 8 to 11 illustrate a method of manufacturing a semiconductor device according to an example embodiment.

A method of manufacturing a semiconductor device according to an example embodiment may include forming the SOC layer 10 containing different types of topological materials, forming the free layer 20 on the SOC layer 10 with a spin direction switchable by current, forming the barrier layer 22 on the free layer 20, and forming the reference layer 24 with a fixed spin direction on the barrier layer 22.

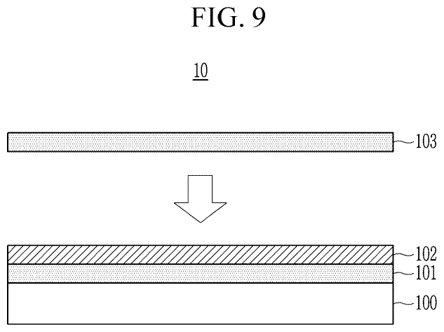

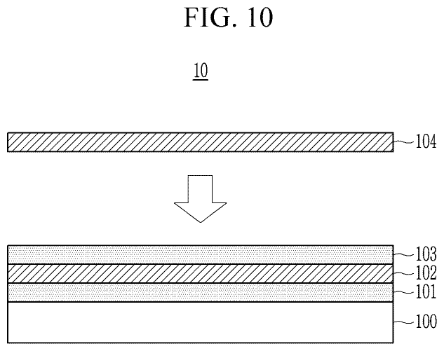

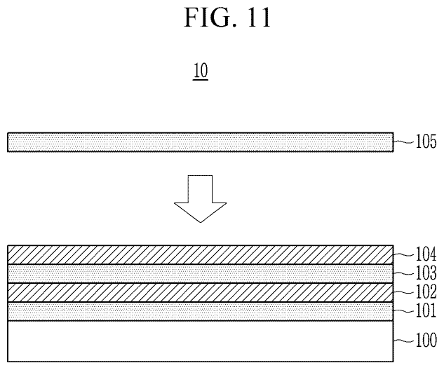

Referring to FIG. 8, the forming of the SOC layer 10 may include providing the substrate 100, forming the topological insulator layer 101 on the substrate 100, and forming the topological semimetal layer 102 on the topological insulator layer 101. Referring to FIG. 9, the forming of the SOC layer 10 may further include forming the topological insulator layer 103 on the topological semimetal layer 102. Referring to FIG. 10, the forming of the SOC layer 10 may further include forming the topological semimetal layer 104 on the topological insulator layer 103. Referring to FIG. 11, the forming of the SOC layer 10 may further include forming the topological insulator layer 105 on the topological semimetal layer 104.

A stacked structure of the free layer 20, the barrier layer 22, and the reference layer 24 may be formed on the SOC layer 10 in the form shown in FIG. 1, but it is not limited to those shown in FIG. 1, and may be formed into a structure including various combinations of one or more free layers and one or more reference layers.

The method of manufacturing the semiconductor device shown in FIGS. 8 to 11 may correspond to a method of forming of the SOC layer 10 of the structure shown in FIG. 2.

In a method of manufacturing a semiconductor device according to an example embodiment, the forming of the SOC layer 11 of the structure shown in FIG. 5 may include providing the substrate 100, forming the topological insulator layer 111 on the substrate 100, forming the topological semimetal layer 112 on the topological insulator layer 111, forming the topological insulator layer 113 on the topological semimetal layer 112, and repeating the stacking to form the free layer 20 on the topological semimetal layer 118.

In a method of manufacturing a semiconductor device according to an example embodiment, the forming of the SOC layer 12 of the structure shown in FIG. 6 may include providing the substrate 100, forming the topological semimetal layer 121 on the substrate 100, forming the topological insulator layer 122 on the topological semimetal layer 121, forming the topological semimetal layer 123 on the topological insulator layer 122, and repeating the stacking to form the free layer 20 on the topological semimetal layer 129.

In a method of manufacturing a semiconductor device according to an example embodiment, the forming of the SOC layer 13 of the structure shown in FIG. 7 may include providing the substrate 100, forming the topological semimetal layer 131 on the substrate 100, forming the topological insulator layer 132 on the topological semimetal layer 131, forming the topological semimetal layer 133 on the topological insulator layer 132, and repeating the stacking to form the free layer 20 on the topological insulator layer 139.

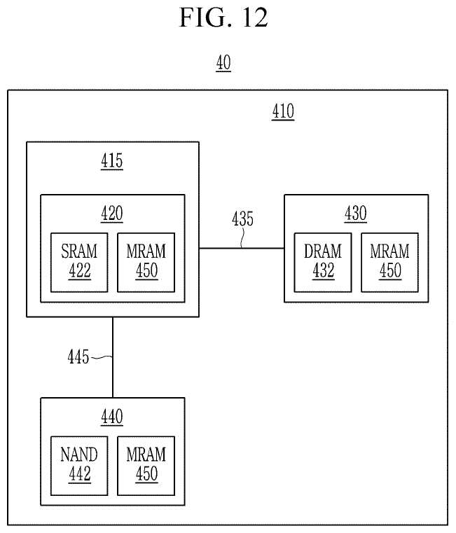

FIG. 12 is a block diagram illustrating a semiconductor system including a semiconductor device according to an example embodiment.

Referring to FIG. 12, a semiconductor system 40 including a semiconductor device according to an example embodiment may include an MRAM 450. In the example embodiment described in relation to FIG. 12, the MRAM 450 may include an SOT-MRAM including a semiconductor device according to the example embodiments described herein. That is, the semiconductor system according to an example embodiment may include a processor 415, a memory 430, and a storage 440, at least one of a cache 420 of the processor 415, the memory 430, or the storage 440 may include a semiconductor device implemented with the SOT-MRAM, and the semiconductor device may include an SOC layer containing different types of topological materials.

The semiconductor system 40 may include a computing device 410. In some example embodiments, the computing device 410 may refer to any electronic device capable of computing by performing arithmetic or logical operations on data. The computing device 410 may be, for example, a server, a workstation, a desktop computer, a laptop computer, a tablet, a smartphone, a control system for other electronic devices, a network-connected storage device, or the like. In some example embodiments, the computing device 410 may include a non-transitory computer-readable storage medium that stores computer-readable instructions that when executed by a processor, configure the computing device 410 to perform one or more operations of the methods disclosed herein.

The computing device 410 may include a processor 415, a memory 430, and a storage 440. The processor 415 may refer to any electronic element that performs arithmetic or logical operations performed by the computing device 410. For example, in some example embodiments, the processor 415 may be a general-purpose processor that executes stored program code. In some example embodiments, the processor 415 may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. For example, the processing circuitry may operate on data stored in the memory 430 or the storage 440 and may include, but is not limited to, a central processing unit (CPU), an arithmetic logic unit (ALU), a digital signal processor, a microcomputer, a System-on-Chip (SoC), a programmable logic unit, a field-programmable gate array (FPGA), application-specific integrated circuit (ASIC), etc. In some other example embodiments, the processor 415 may be a controller for a storage device, networking device, or the like.

The processor 415 may include a cache 420. In some example embodiments, the cache 420 may store data for use by the processor 415. In some example embodiments, the cache 420 is smaller and faster than the memory 430 and may replicate data to frequently used locations in the memory 430. In some example embodiments, the processor 415 may include a plurality of caches 420. In some example embodiments, the cache 420 may include one or more types of memory media for storing data, such as a static random access memory (SRAM) 422, the MRAM 450, or the like. For example, in some example embodiments, the cache 420 may include the SRAM 422. In some other example embodiments, the cache 420 may include the MRAM 450. In some other example embodiments, the cache 420 may include a combination of the SRAM 422, the MRAM 450, and other types of memory media.

The memory 430 may be connected to the processor 415 by a memory bus 435. In some example embodiments, the memory 430 may store data directly addressable by the processor 415. In some example embodiments, the memory 430 may include one or more types of memory media for storing data, such as a dynamic random access memory (DRAM) 432, the MRAM 450, or the like. For example, in some example embodiments, the memory 430 may include the DRAM 432. In some other example embodiments, the memory 430 may include the MRAM 450. In some other example embodiments, the memory 430 may include a combination of the DRAM 432, the MRAM 450, and other types of memory media.

The storage 440 may be connected to the processor 415 by a storage bus 445. In some example embodiments, the storage bus 445 may be a peripheral bus of the computing device 410, such as a peripheral component interconnect express (PCIe) bus, a serial advanced technology attachment (SATA) bus, a parallel advanced technology attachment (PATA) bus, a small computer system interface (SCSI) bus, a FireWire bus, a universal serial bus (USB) or a PCIe advanced switching (PCIe-AS) bus. In some example embodiments, the storage 440 may store data that may not be addressed directly by the processor 415 but may be accessed through one or more storage controllers. In some example embodiments, the storage 440 may be larger than the memory 430. In some example embodiments, the storage 440 may include one or more types of storage media for storing data, such as a hard disk drive, a NAND flash memory 442, the MRAM 450, or the like. For example, in some example embodiments, the storage 440 may include the NAND flash memory 442. In some other example embodiments, the storage 440 may include the MRAM 450. In some other example embodiments, the storage 440 may include a combination of the NAND flash memory 442, the MRAM 450, and other types of storage media.

In some example embodiments, the MRAM 450 may be used to store data in the cache 420, the memory 430, the storage 440, or other components that store data. For example, the computing device 410 may include the MRAM 450 in the cache 420, the memory 430, and the storage 440. In some other example embodiments, the computing device 410 may use the MRAM 450 for the memory 430, and other types of memory or storage media for the cache 420 or the storage 440. In some other example embodiments, the computing device 410 may use the MRAM 450 for the storage 440, and other types of memory media for the cache 420 and the memory 430. Additionally, some types of computing devices 410 (e.g., in a microcontroller) may include the memory 430 without the storage 440 if the memory 430 is non-volatile, or may include the memory 430 without the cache 420 for a dedicated processor 415. Various combinations of the cache 420, the memory 430, or the storage 440 and use of the MRAM 450 for the cache 420, the memory 430, the storage 440, or other applications will become apparent in consideration of the content disclosed herein.

According to the example embodiments described herein, it is possible to effectively engineer the physical quantities of the SOT by providing SOT layers containing different types of topological materials.

While some example embodiments of the present disclosure have been described in detail, it is to be understood that the disclosure is not limited to the disclosed example embodiments, but on the contrary, is intended to cover various modifications and equivalent arrangements included within the spirit and scope of the appended claims.

What is claimed is:

1. A semiconductor device, comprising:
a reference layer with a fixed spin direction;
a barrier layer below the reference layer;
a free layer below the barrier layer and having a spin direction switchable by current; and
a spin orbit coupling (SOC) layer below the free layer and containing different types of topological materials.

2. The semiconductor device of claim 1, wherein
the different types of topological materials include a first topological material and a second topological material, and
the SOC layer comprises
a substrate, and
a thin film layer on the substrate, the thin film layer including the first topological material and the second topological material that are alternately stacked on each other.

3. The semiconductor device of claim 2, wherein
the first topological material comprises a topological insulator, and
the second topological material comprises a topological semimetal.

4. The semiconductor device of claim 3, wherein
the topological insulator comprises at least one of Bi₂Te₃, Sb₂Te₃, or Bi₂Se₃.

5. The semiconductor device of claim 3, wherein
the topological semimetal comprises at least one of WTe₂, ZrTe₅, EuMnBi₂, or CaIrO₂.

6. The semiconductor device of claim 3, wherein
the topological insulator comprises a first topological insulator layer and a second topological insulator layer,
the topological semimetal comprises a first topological semimetal layer,
the first topological insulator layer is on the substrate,
the first topological semimetal layer is on the first topological insulator layer,
the second topological insulator layer is on the first topological semimetal layer, and
the free layer is on the second topological insulator layer.

7. The semiconductor device of claim 3, wherein
The topological insulator comprises a first topological insulator layer,
the topological semimetal comprises a first topological semimetal layer,
the first topological insulator layer is on the substrate,
the first topological semimetal layer is on the first topological insulator layer, and
the free layer is on the first topological semimetal layer.

8. The semiconductor device of claim 3, wherein
the topological insulator comprises a first topological insulator layer,
the topological semimetal comprises a first topological semimetal layer and a second topological semimetal layer,
the first topological semimetal layer is on the substrate,
the first topological insulator layer is on the first topological semimetal layer,
the second topological semimetal layer is on the first topological insulator layer, and
the free layer is on the second topological semimetal layer.

9. The semiconductor device of claim 3, wherein
the topological insulator comprises a first topological insulator layer,
the topological semimetal comprises a first topological semimetal layer,
the first topological semimetal layer is on the substrate,
the first topological insulator layer is on the first topological semimetal layer, and
the free layer is on the first topological insulator layer.

10. The semiconductor device of claim 2, wherein
the substrate comprises at least one of silicon or sapphire.

11. A semiconductor system, comprising:
processing circuitry;
a memory; and
a storage,
wherein at least one of a cache of the processing circuitry, the memory, or the storage comprises a semiconductor device implemented with a spin orbit torque magnetic random access memory (SOT-MRAM), and
the semiconductor device comprises a spin orbit coupling (SOC) layer containing different types of topological materials.

12. The semiconductor system of claim 11, wherein the SOC layer comprises:
a substrate; and
a thin film layer on the substrate, the thin film layer including the different types of topological materials, the different types of topological materials including at least one first topological material and at least one second topological material that are alternately stacked on each other.

13. The semiconductor system of claim 12, wherein
the at least one first topological material comprises a topological insulator, and
the at least one second topological material comprises a topological semimetal.

14. The semiconductor system of claim 13, wherein
The topological insulator comprises at least one of Bi₂Te₃, Sb₂Te₃, or Bi₂Se₃.

15. The semiconductor system of claim 13, wherein
the topological semimetal comprises at least one of WTe₂, ZrTe₅, EuMnBi₂, or CaIrO₂.

16. A method of manufacturing a semiconductor device, comprising:
forming a spin orbit coupling (SOC) layer containing different types of topological materials;
forming a free layer on the SOC layer with a spin direction switchable by current;
forming a barrier layer on the free layer; and
forming a reference layer with a fixed spin direction on the barrier layer.

17. The method of manufacturing the semiconductor device of claim 16, wherein the forming of the SOC layer comprises:
providing a substrate; and
providing the different types of topological materials on the substrate by
forming a first topological insulator layer on the substrate,
forming a first topological semimetal layer on the first topological insulator layer, and
forming a second topological insulator layer on the first topological semimetal layer.

18. The method of manufacturing the semiconductor device of claim 16, wherein the forming of the SOC layer comprises:
providing a substrate; and
providing the different types of topological materials on the substrate by
forming a first topological insulator layer on the substrate, and
forming a first topological semimetal layer on the first topological insulator layer.

19. The method of manufacturing the semiconductor device of claim 16, wherein the forming of the SOC layer comprises:
providing a substrate; and
providing the different types of topological materials on the substrate by
forming a first topological semimetal layer on the substrate,
forming a first topological insulator layer on the first topological semimetal layer, and
forming a second topological semimetal layer on the first topological insulator layer.

20. The method of manufacturing the semiconductor device of claim 16, wherein the forming of the SOC layer comprises:
providing a substrate; and
providing the different types of topological materials on the substrate by
forming a first topological semimetal layer on the substrate, and
forming a first topological insulator layer on the first topological semimetal layer.
